(19) United States
(12) Patent Application Publication
(10) Pub. No.: US 2004/0066217 A1
(43) Pub. Date: Apr. 8, 2004

(54) Apparatus and method for providing a signal having a controlled transition characteristic

(76) Inventors: David G. Daniels, Dallas, TX (US); Alan Johnson, Richardson, TX (US)

Correspondence Address: TEXAS INSTRUMENTS INCORPORATED, P O BOX 655474, M/S 3999, DALLAS, TX, 75265

(21) Appl. No.: 10/263,136

(22) Filed: Oct. 2, 2002

(51) Int. Cl. H03K 3/00

(52) U.S. Cl. 327/99

(57) ABSTRACT

An apparatus for providing a signal having a controlled transition characteristic at an output terminal includes: (A) A signal comparing unit having a plurality of input loci and at least one output locus, receiving a first signal at a first input locus and receiving a second signal at a second input locus. The signal comparing unit presents at least one gating signal having a value depending on relative values of the first signal and the second signal at the at least one output locus. (B) A switching unit coupled with the at least one output locus and receiving the first signal and the second signal. The switching unit switchingly controlling coupling of the first signal or of the second signal with the output terminal in response to the at least one gating signal.

### BACKGROUND OF THE INVENTION

The present invention is directed to power supply devices, and especially to power supply devices that present a signal having a controlled transition characteristic, such as a power up transition characteristic or a power down transition characteristic.

When a circuit designer employs devices in a system that require a plurality of supply voltages, such as dual supply logic devices, consideration must be given to the relative voltage levels and timing of various voltage supplies during power up and power down operations of the devices. Devices that require a plurality of supply voltages include, by way of example and not by way of limitation, digital signal processor (DSP), field programmable gate array (FPGA) or application specific integrated circuit (ASIC) devices. The various power supply devices that operate to support a device (the supported device) likely include a core power supply (i.e., a power supply device providing a fundamental or common power requirement of the supported device), and one or more other power supplies that provide power to the supported device via input-output (IO) circuit bocks—sometimes also referred to as IO buffers. IO buffers work in cooperation with the core power supply device and other power supply devices, as appropriate, in providing other power requirements of the supported device. The various power supply sources (i.e., the core power supply and the various other power supply devices operating through IO buffers) generally include isolation structures to isolate a respective power supply device from the supported device until appropriate power may be provided by a respective power supply device. During power up and power down operations of the supported device, starting points and ramp rates among the various supply devices (i.e., the core power supply or other power supply devices) may differ. That is, the various power supply devices exhibit different characteristics in starting points and ramp profiles power up operations and during power down operations. Such different characteristics during power up and during power down operations will be referred to generically herein as transition characteristics indicating characteristics during transitioning to an operational state from an off state (i.e., during a power down operation), and indicating characteristics during transitioning to an off state from an operational state (i.e., during a power up operation). During such transitions, isolation structures in some power supply devices may become forward biased so that current may flow in a respective isolation structure at a time when no power is supposed to be provided by the respective power supply device. Such improperly timed currents can reduce the usable life of the supported device, can trigger latch-up of the supported device or may result in failure of the supported device.

System designers addressing issues such as bus contention may require power supply sequencing to be implemented. In such designs, the core power supply device is preferably powered up at the same time as the other power supply devices operating with respective IO buffers. Such substantially simultaneous powering up of various power supply devices avoids the core power supply device seeing a high current draw, as would occur if the core power supply device is powered up and the other power supply devices operating with respective IO buffers are not powered up. A high current draw may be a result, for example, of an un-initialized logic portion within a DSP, FPGA or ASIC device. Such high current may damage the supported device if the high current condition exists for an extended time. The duration of a high current condition that is harmful for a particular supported device may vary from device to device. Repeated occasions of such high current conditions, even though each occasion may be of relatively short duration, may also contribute to damaging a supported device. System designers seek to alleviate, or preferably avoid, such high current conditions by decreasing the time that elapses between powering up the core power supply device and powering up the various other power supply devices operating with IO circuit blocks or buffers. The problems described briefly here are exacerbated and further complicated when a system involves multiple DSP, FPGA or ASIC devices, each having different voltage requirements. Such a system provide a greater number of power supply rails than a system involving a single DSP.

Thus, there is a need for a multiple output power supply device with simultaneous sequencing that can facilitate effecting simultaneous startup of one or more core power supply devices and other power supply devices operating with IO buffers. Such a capability for simultaneous startup provides a robust system solution for minimizing timing and voltage level differences among various supply rails, solves bus contention issues and minimizes risk of latch up in supported devices.

### SUMMARY OF THE INVENTION

An apparatus for providing a signal having a controlled transition characteristic at an output terminal includes: (a) A signal comparing unit having a plurality of input loci and at least one output locus, receiving a first signal at a first input locus and receiving a second signal at a second input locus. The signal comparing unit presents at least one gating signal having a value depending on relative values of the first signal and the second signal at the at least one output locus. (b) A switching unit coupled with the at least one output locus and receiving the first signal and the second signal. The switching unit switchingly controlling coupling of the first signal or of the second signal with the output terminal in response to the at least one gating signal.

It is, therefore, an object of the present invention to provide an apparatus and method for providing a signal having a controlled transition characteristic.

Further objects and features of the present invention will be apparent from the following specification and claims when considered in connection with the accompanying drawings, in which like elements are labeled using like reference numerals in the various figures, illustrating the preferred embodiments of the invention.

### DESCRIPTION OF THE DRAWINGS

FIG. 1 is a graphic representation of desired signal transitions during startup of a representative electrical device.

FIG. 2 is a graphic representation of desired signal transitions during shutdown of a representative electrical device.

FIG. 3 is an electrical schematic diagram of a first embodiment of an apparatus for providing a signal having a controlled transition characteristic according to the present invention.

FIG. 4 is an electrical schematic diagram of a second embodiment of an apparatus for providing a signal having a controlled transition characteristic according to the present invention.

FIG. 5 is an electrical schematic diagram of a system employing a plurality of apparatuses for providing a signal having a controlled transition characteristic according to the present invention.

FIG. 6 is a flow diagram illustrating the method of the present invention.

### DETAILED DESCRIPTION OF THE PREFERRED EMBODIMENT

The preferred embodiment of the apparatus of the present invention effects simultaneous power up and power down of multiple power supplies using the output of a first power supply device as a “tracking reference” for other power supply devices via IO buffers. The other power supply devices may be referred to as tracking supplies. There are usually several tracking supplies, each of which provides a respective reference voltage. In the preferred embodiment of the invention, the tracking reference power supply is the highest regulated output voltage in the system, typically 3.3 volts or greater.

A system switching regulator that provides various voltages as required in a system employs a tracking reference voltage from a tracking reference power supply (also sometimes referred to as a core power supply) and compares the tracking reference voltage with each respective reference voltage to be provided to a supported device in the system. The system switching regulator employs a plurality of apparatuses according to present invention to effect the desired comparison of each respective reference voltage with the tracking reference voltage and regulate a respective output signal for each respective apparatus to the lower of the two voltages: the tracking reference voltage and the respective reference voltage.

In such an arrangement, each of the respective apparatuses is employed to compare a respective reference voltage to the same tracking reference voltage for a particular supported device. By such an arrangement the voltages for a particular supported device will all track together in rising (e.g., during power up operations) or will all track together in falling (e.g., during power down operations), at least in so far as when the lower of the voltages is the tracking reference voltage. In such manner, asynchronicity in time or in magnitude is reduced among various voltages supplied to a particular supported device during transition operations, such as power up operations and power down operations.

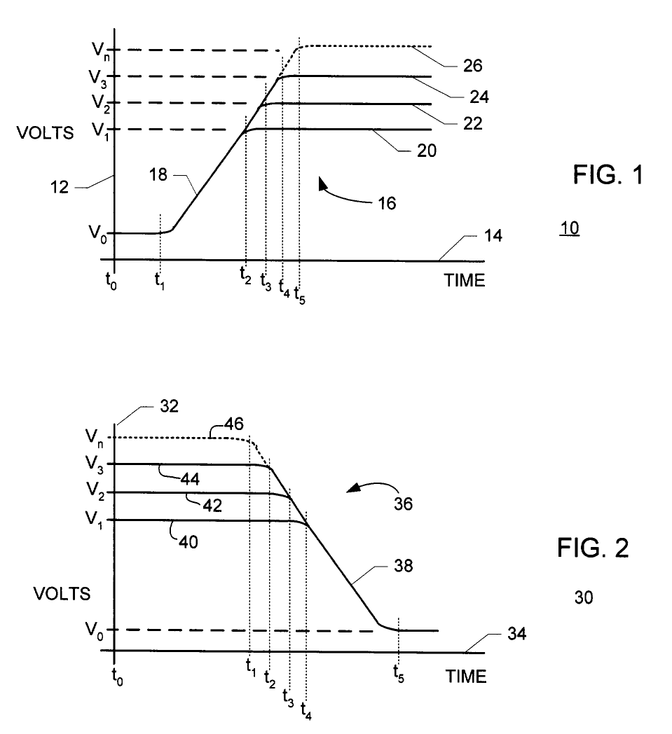

FIG. 1 is a graphic representation of desired signal transitions during power up of a representative electrical device. In FIG. 1, a graphic plot 10 is displayed with a first axis 12 indicating volts and a second axis 14 indicating time. A family of curves 16 indicating a transition characteristic of a system or device during a power up operation includes a common curve 18 that is established substantially in the interval t₀-t₂. It is in common curve 18 during interval t₀-t₂ that each curve of family of curves 16 is substantially identical. This is a desirable signal dynamic to ensure that no forward biasing of isolation circuitry occurs to occasion undesired current flow to a supported device during transition of the supported device such as during a power up operation, as discussed earlier herein

As each respective curve of family of curves 16 differs from common curve 18, a separate curve is established. Common curve 18 begins at time t₀ substantially at a voltage level V₀, and remains at voltage level V₀ until approximately time t₁. Substantially at time t₁, common curve 18 rises and continues rising until approximately time t₂. Such a rising transition characteristic indicates a power up operation for a device or system. Substantially at time t₂ a first voltage V₁ is established for supply to a device (not shown in FIG. 1), as indicated by a curve 20 deviating from common curve 18. Similarly, substantially at time t₃ a second voltage V₂ is established for supply to a supported device (not shown in FIG. 1), as indicated by a curve 22 deviating from common curve 18. Substantially at time t₄ a third voltage V₃ is established for supply to a supported device (not shown in FIG. 1), as indicated by a curve 24 deviating from common curve 18. Substantially at time t₄ a fourth, or nth, voltage Vₙ is established for supply to a supported device (not shown in FIG. 1), as indicated by a curve 26 deviating from common curve 18. In such an arrangement, when a supported device (not shown in FIG. 1) undergoes a power up operation, the various supply voltages V₁, V₂, V₃, Vₙ provided to the supported device ramp up from a substantially common starting point (i.e., at voltage V₀, time t₀). Further, the various supply voltages V₁, V₂, V₃, Vₙ ramp up substantially along a common transition curve 18 during the interval t₀-t₂. After time t₂ (when supply voltage V₁ is established), remaining supply voltages V₂, V₃, Vₙ continue to ramp up together until time t₃ (when supply voltage V₂ is established). After time t₃ remaining supply voltages V₃, Vₙ continue to ramp up together until time t₄ (when supply voltage V₃ is established). After time t₄ remaining supply voltage Vₙ continues to ramp up until time t₅ (when supply voltage Vₙ is established). The subscript “n” is employed to indicate that any number of supply voltages may be desired for a supported device. In the preferred embodiment of the present invention supply voltage Vₙ, the highest of the supply voltages V₁, V₂, V₃, Vₙ, is selected as the tracking reference voltage provided by a core power supply device. By such an arrangement, using the apparatus of the present invention to select the lower of two voltages ensures that supply voltages V₁, V₂, V₃, Vₙ will have a common starting point and track together along a common transition curve until each respective supply voltage V₁, V₂, V₃, Vₙ is established.

FIG. 2 is a graphic representation of desired signal transitions during shutdown of a representative electrical device. In FIG. 2, a graphic plot 30 is displayed with a first 32 indicating volts and a second axis 34 indicating time. A family of curves 36 indicating a transition characteristic of a system or device during a power down operation includes a common curve 38 that is established substantially in the interval t₄-t₅. It is in common curve 38 during interval t₄-t₅ that each curve of family of curves 36 is substantially identical. This is a desirable signal dynamic to ensure that no forward biasing of isolation circuitry occurs to occasion undesired current flow to a supported device during transition of the supported device such as during a power down operation, as discussed earlier herein.

As the supported device (not shown in FIG. 2) powers down, each supply voltage V₁, V₂, V₃, Vₙ remains at a substantially constant level during a time interval t₀-t₁. Each supply voltage transitions downward in a sequential order as the supported device (not shown in FIG. 2) performs a power down operation. Thus, substantially at a time t₁ supply voltage Vₙ begins to transition downward along a curve 38 in a power down operation. Similarly, substantially at a time t₂ supply voltage V₃ begins to transition downward along curve 38; substantially at a time t₃ supply voltage V₂ begins to transition downward along curve 38; and substantially at a time t₄ supply voltage V₁ begins to transition downward along curve 38. Such a falling transition characteristic indicates a power down operation for a device or system.

In such an arrangement, when a supported device (not shown in FIG. 2) undergoes a power down operation, the various supply voltages V₁, V₂, V₃, Vₙ provided to the supported device ramp down from their respective voltage levels substantially along a common transition curve 38 during the interval t₄-t₅. Before time t₄ respective supply voltages V₁, V₂, V₃, Vₙ sequentially ramp down substantially along curve 38 until time t₄,when all supply voltages V₁, V₂, V₃, Vₙ are ramping down. After time t₄ supply voltages V₁, V₂, V₃, Vₙ continue to ramp down together until time t₅ when the power down operation is complete. The subscript “n” is employed to indicate that any number of supply voltages may be desired for a supported device. In the preferred embodiment of the present invention supply voltage Vₙ, the highest supply voltage of supply voltages V₁, V₂, V₃, Vₙ, is selected as the tracking reference voltage provided by a core power supply device. By such an arrangement, using the apparatus of the present invention to select the lower of two voltages ensures that supply voltages V₁, V₂, V₃, Vₙ will track together along a common transition curve until each respective supply voltage V₁, V₂, V₃, Vₙ is powered down.

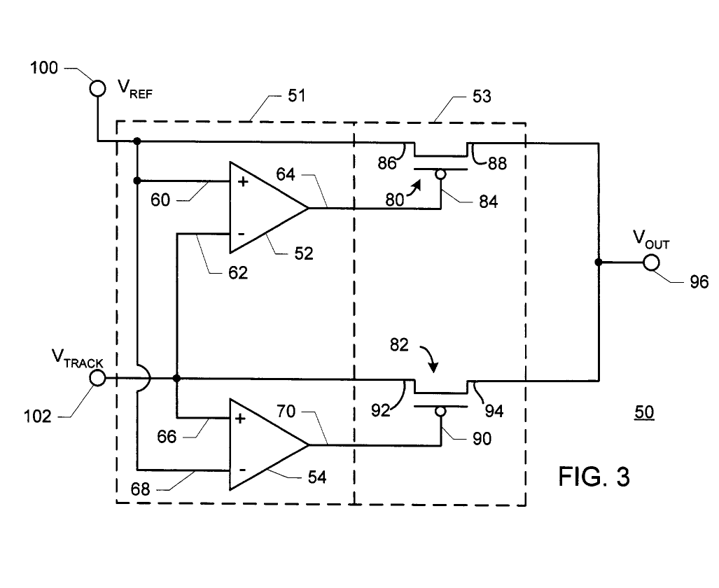

FIG. 3 is an electrical schematic diagram of a first embodiment of an apparatus for providing a signal having a controlled transition characteristic according to the present invention. In FIG. 3, an apparatus 50 includes a signal comparing unit 51 and a switching unit 53. Signal comparing unit 51 includes a first error amplifier 52 and a second error amplifier 54. First error amplifier 52 has a noninverting input locus 60, an inverting input locus 62 and an output locus 64. Second error amplifier 54 has a noninverting input locus 66, an inverting input locus 68 and an output locus 70.

Switching unit 53 includes a first switching device 80 and a second switching device 82. First switching device 80 responds to gating signals applied at a gate 84 to switchingly control coupling of signals applied at a first switch input locus 86 with a first switch output locus 88. Gate 84 is coupled with output locus 64. Second switching device 82 responds to gating signals applied at a gate 90 to switchingly control coupling of signals applied at a second switch input locus 92 with a second switch output locus 94. Gate 90 is coupled with output locus 70. Preferably switching devices 80, 82 are PMOS devices. Establishing switching device 80 as a PMOS device ensures that when a gating signal applied to gate 84 is high, switching device 80 is open and no connection is established between first switch input locus 86 and first switch output locus 88, and when a gating signal applied to gate 84 is low, switching device 80 couples signals applied at first switch input locus 86 with first switch output locus 88. Similarly, establishing switching device 82 as a PMOS device ensures that when a gating signal applied to gate 90 is high, switching device 82 is open and no connection is established between second switch input locus 92 and second switch output locus 94, and when a gating signal applied to gate 90 is low, switching device 82 couples signals applied at second switch input locus 92 with second switch output locus 94. First switch output locus 88 and second switch output locus 94 are coupled with an apparatus output locus 96. reference voltage V_{REF} for a supported device (not shown in FIG. 3) is applied to a first apparatus input locus 100. A tracking reference voltage V_{TRACK} is applied to a second apparatus input locus 102. Preferably, reference voltage V_{REF} is a lower voltage than tracking reference voltage V_{TRACK}. In the representative apparatus 50 of the invention illustrated in FIG. 3, V_{TRACK} may be regarded as represented by voltage Vₙ in FIGS. 1 and 2, and V_{REF} may be regarded as represented by any one of voltages V₁, V₂, V₃ in FIGS. 1 and 2.

First apparatus input locus 100 is coupled with noninverting input locus 60, with inverting input locus 68 and with first switch input locus 86. Second apparatus input locus 102 is coupled with noninverting input locus 66, with inverting input locus 62 and with second switch input locus 92.

In operation, when V_{REF} is greater than V_{TRACK}, an output signal appearing at output locus 64 will be a high signal so that a gating signal appearing at gate 84 is high. In those circumstances, switching device 80 is open and no connection is established between first switch input locus 86 and first switch output locus 88. The condition of V_{REF} being greater than V_{TRACK} further results in an output signal appearing at output locus 70 being a low signal so that a gating signal appearing at gate 90 is low. In those circumstances, switching device 82 couples signals applied at second switch input locus 92 with second switch output locus 94. By establishing such coupling, switching device 82 couples V_{TRACK} with apparatus output locus 96.

When V_{TRACK} is greater than V_{REF}, an output signal appearing at output locus 70 will be a high signal so that a gating signal appearing at gate 90 is high. In those circumstances, switching device 82 is open and no connection is established between second switch input locus 92 and second switch output locus 94. The condition of V_{TRACK} being greater than V_{REF} further results in an output signal appearing at output locus 64 being a low signal so that a gating signal appearing at gate 84 is low. In those circumstances, switching device 80 couples signals applied at first switch input locus 86 with first switch output locus 88. By establishing such coupling, switching device 80 V_{REF} with apparatus output locus 96. Apparatus 50 thus selectively applies the lower-valued one of V_{REF} or V_{TRACK} to apparatus output locus 96.

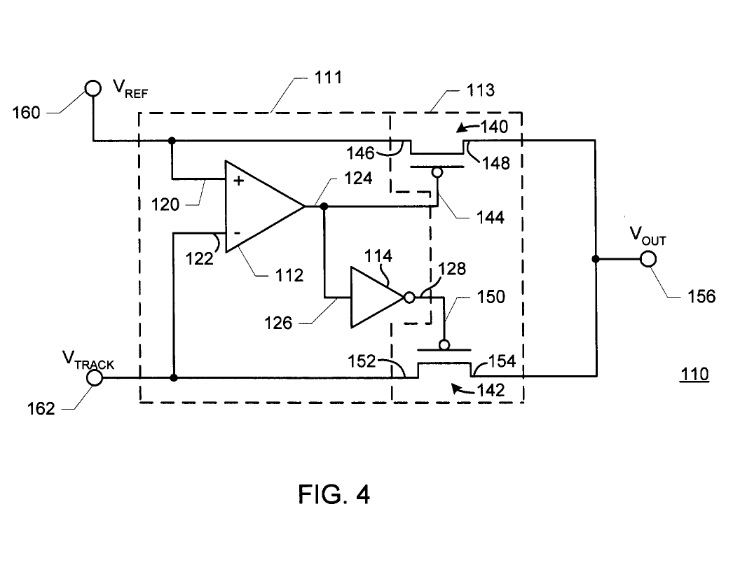

FIG. 4 is an electrical schematic diagram of a second embodiment of an apparatus for providing a signal having a controlled transition characteristic according to the present invention. In FIG. 4, an apparatus 110 includes a signal comparing unit 111 and a switching unit 113. Signal comparing unit 111 includes an error amplifier 112 and an inverter 114. Error amplifier 112 has a noninverting input locus 120, an inverting input locus 122 and an output locus 64. Inverter 114 has an input locus 126 and an output locus 128. Input locus 126 is coupled with output locus 124 of error amplifier 112.

Switching unit 113 includes a first switching device 140 and a second switching device 142. First switching device 140 responds to gating signals applied at a gate 144 to switchingly control coupling of signals applied at a first switch input locus 146 with a first switch output locus 148. Gate 144 is coupled with output locus 124. Second switching device 142 responds to gating signals applied at a gate 150 to switchingly control coupling of signals applied at a second switch input locus 152 with a second switch output locus 154. Gate 150 is coupled with output locus 128. Preferably switching devices 140, 142 are PMOS devices. Establishing switching device 140 as a PMOS device ensures that when a gating signal applied to gate 144 is high, switching device 140 is open and no connection is established between first switch input locus 146 and first switch output locus 148, and when a gating signal applied to gate 144 is low, switching device 140 couples signals applied at first switch input locus 146 with first switch output locus 148. Similarly, establishing switching device 142 as a PMOS device ensures that when a gating signal applied to gate 150 is high, switching device 142 is open and no connection is established between second switch input locus 152 and second switch output locus 154, and when a gating signal applied to gate 150 is low, switching device 142 couples signals applied at second switch input locus 152 with second switch output locus 154. First switch output locus 148 and second switch output locus 154 are coupled with an apparatus output locus 156.

A reference voltage V_{REF} for a supported device (not shown in FIG. 4) is applied to a first apparatus input locus 160. A tracking reference voltage V_{TRACK} is applied to a apparatus input locus 162. Preferably, reference voltage V_{REF} is a lower voltage than tracking reference voltage V_{TRACK}. In the representative apparatus 110 of the invention illustrated in FIG. 4, V_{TRACK} may be regarded as represented by voltage Vₙ in FIGS. 1 and 2, and V_{REF} may be regarded as represented by any one of voltages V₁, V₂, V₃ in FIGS. 1 and 2.

First apparatus input locus 160 is coupled with noninverting input locus 120 and with first switch input locus 146. Second apparatus input locus 162 is coupled with noninverting input locus 122 and with second switch input locus 152.

In operation, when V_{REF} is greater than V_{TRACK}, an output signal appearing at output locus 124 will be a high signal so that a gating signal appearing at gate 144 is high. In those circumstances, switching device 140 is open and no connection is established between first switch input locus 146 and first switch output locus 148. The output signal appearing at output locus 124 being high results in an output signal appearing at output locus 128 being a low signal so that a gating signal appearing at gate 150 is low. In those circumstances, switching device 142 couples signals applied at second switch input locus 152 with second switch output locus 154. By establishing such coupling, switching device 142 couples V_{TRACK} with apparatus output locus 156.

When V_{TRACK} is greater than V_{REF}, an output signal appearing at output locus 124 will be a low signal so that a gating signal appearing at gate 144 is low. In those circumstances, switching device 140 couples signals applied at first switch input locus 146 with first switch output locus 148. By establishing such coupling, switching device 80 couples V_{REF} with apparatus output locus 96. The output signal appearing at output locus 124 being low results in an output signal appearing at output locus 128 being a high signal so that a gating signal appearing at gate 150 is high so that switching device 142 is open and no connection is established between second switch input locus 152 and second switch output locus 154. Apparatus 110 thus selectively applies the lower-valued one of V_{REF} or V_{TRACK} to apparatus output locus 156.

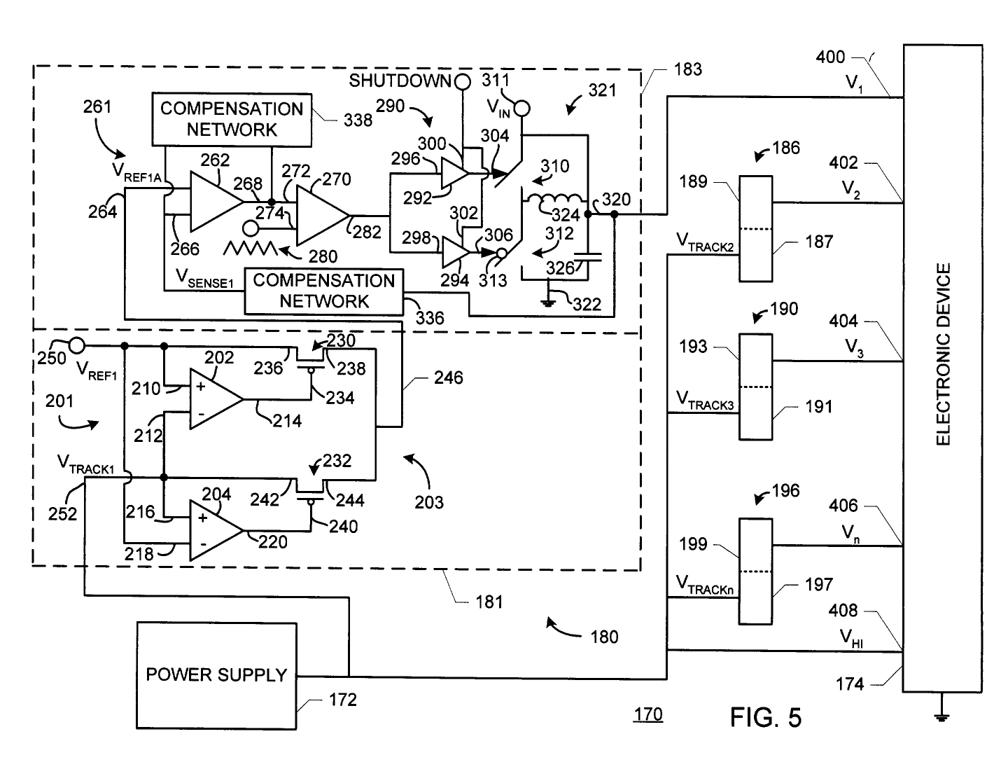

FIG. 5 is an electrical schematic diagram of a system employing a plurality of apparatuses for providing a signal having a controlled transition characteristic according the present invention. In FIG. 5, a system 170 provides power for a supported device 174. System 170 includes a core power supply device 172, a first power supply device 180, a second power supply device 186, a third power supply device 190 and an nth power supply device 196. First power supply device 180 includes a signal selecting unit 181 and a switching power supply unit 183. Second power supply device 186 includes a signal selecting unit 187 and a switching power supply unit 189. Third power supply device 190 includes a signal selecting unit 191 and a switching power supply unit 193. Nth power supply device 196 includes a signal selecting unit 197 and a switching power supply unit 199.

Core power supply device 172 provides a tracking voltage V_{TRACK} to each power supply device 180, 186, 190, 196. Core power supply device 172 also provides a voltage V_{HI} to supported device 174. Each of power supply devices 180, 186, 190, 196 is substantially the same configuration so, in the interest of avoiding prolixity and in the interest of simplifying the explanation of FIG. 5, only one representative power supply 180 will be described in detail.

Signal selecting unit 181 is substantially similar with apparatus 50 (FIG. 3). Thus, signal selecting unit 181 includes a signal comparing unit 201 and a switching unit 203. Signal comparing unit 201 includes a first error amplifier 202 and a second error amplifier 204. First error amplifier 202 has a noninverting input locus 210, an inverting input locus 212 and an output locus 214. Second error amplifier 204 has a noninverting input locus 216, an inverting input locus 218 and an output locus 220.

Switching unit 213 includes a first switching device 230 and a second switching device 232. First switching device 230 responds to gating signals applied at a gate 234 to switchingly control coupling of signals applied at a first switch input locus 236 with a first switch output locus 238. Gate 234 is coupled with output locus 214. Second switching device 232 responds to gating signals applied at a gate 240 to switchingly control coupling of signals applied at a second switch input locus 242 with a second switch output locus 244. Gate 240 is coupled with output locus 220. Preferably switching devices 230, 232 are PMOS devices. Establishing switching device 230 as a PMOS device ensures that when a gating signal applied to gate 234 is high, switching 230 is open and no connection is established between first switch input locus 236 and first switch output locus 238, and when a gating signal applied to gate 234 is low, switching device 230 couples signals applied at first switch input locus 236 with first switch output locus 238. Similarly, establishing switching device 232 as a PMOS device ensures that when a gating signal applied to gate 240 is high, switching device 232 is open and no connection is established between second switch input locus 242 and second switch output locus 244, and when a gating signal applied to gate 240 is low, switching device 232 couples signals applied at second switch input locus 242 with second switch output locus 244. First switch output locus 238 and second switch output locus 244 are coupled with an apparatus output locus 246.

A reference voltage V_{REF} for a supported device (not shown in FIG. 5) is applied to a first apparatus input locus 250. A tracking reference voltage V_{TRACK} is applied to a second apparatus input locus 252. Preferably, reference voltage V_{REF} is a lower voltage than tracking reference voltage V_{TRACK}. In the representative signal selecting unit 181 illustrated in FIG. 5, V_{TRACK} may be regarded as represented by voltage Vₙ in FIGS. 1 and 2, and V_{REF} may be regarded as represented by any one of voltages V₁, V₂, V₃ in FIGS. 1 and 2.

First apparatus input locus 250 is coupled with noninverting input locus 210, with inverting input locus 218 and with first switch input locus 236. Second apparatus input locus 252 receives voltage V_{TRACK} from core power supply device 172 and is coupled with noninverting input locus 216, with inverting input locus 212 and with second switch input locus 242.

In operation, when V_{REF} is greater than V_{TRACK}, an output signal appearing at output locus 214 will be a high signal so that a gating signal appearing at gate 234 is high. In those circumstances, switching device 230 is open and no connection is established between first switch input locus 236 and first switch output locus 238. The condition of V_{REF} being greater than V_{TRACK} further results in an output signal appearing at output locus 220 being a low signal so that a gating signal appearing at gate 240 is low. In those circumstances, switching device 232 couples signals applied at second switch input locus with second switch output locus 244. By establishing such coupling, switching device 232 couples V_{TRACK} with apparatus output locus 246.

When V_{TRACK} is greater than V_{REF}, an output signal appearing at output locus 220 will be a high signal so that a gating signal appearing at gate 240 is high. In those circumstances, switching device 232 is open and no connection is established between second switch input locus 242 and second switch output locus 244. The condition of V_{TRACK} being greater than V_{REF} further results in an output signal appearing at output locus 214 being a low signal so that a gating signal appearing at gate 234 is low. In those circumstances, switching device 230 couples signals applied at first switch input locus 236 with first switch output locus 238. By establishing such coupling, switching device 230 couples VREF with apparatus output locus 246. Signal selecting unit 181 thus selectively applies the lower-valued one of V_{REF} or V_{TRACK} to apparatus output locus 246. The signal presented at apparatus output locus 246 is provided to switching power supply unit 183 as an input reference voltage V_{REFIA}.

Switching power supply 183 includes a difference-indicating unit 261, a switching unit 290, and an output unit 321. Difference-indicating unit 261 may be embodied in any unit that generates a pulse signal that represents difference between an extant signal at an output locus and a desired signal at that output locus. One example of such a pulse signal is a pulse width modulated signal having a duty cycle that represents the error between an extant signal at an output locus and a desired signal at that output locus. In the exemplary embodiment of difference-indicating unit 261 illustrated in FIG. 5, difference-indicating unit 261 includes an error amplifier unit, or device 262 receiving a reference signal V_{REFIA} at a reference terminal 264, and receiving a sense signal V_{SENSEI} at a sense terminal 266. Error amplifier 262 generates an ERROR signal at an error output or error locus 268. The ERROR signal represents the difference between reference signal V_{REFIA} and sense signal V_{SENSEI}.

Switching power supply 183 further includes a pulse comparator unit or device, also sometimes described as a pulse width modulation comparator 270. Pulse comparator unit 270 receives the ERROR signal from error locus 268 at an input terminal 272. Pulse unit 270 also receives a periodic reference signal at an input terminal 274 from a periodic signal source (not shown in FIG. 5), such as an oscillator that generates a periodic signal preferably in the form of a “sawtooth” signal, as indicated generally by a waveform 280. Pulse comparator unit 270 generates a PULSE signal at a pulse signal locus 282 that represents the difference between the ERROR signal received at terminal 272 and the periodic reference signal received at terminal 274.

Pulse signal locus 282 is coupled with a switching unit 290. Switching unit 290 includes a high side switching FET (Field Effect Transistor) driver 292 and a low side switching FET driver 294. FET driver 292 has an input terminal 296 that is connected with pulse signal locus 282 so that FET driver 292 receives the PULSE signal from pulse signal locus 282 as an input signal. FET driver 294 has an input terminal 298 that is connected with pulse signal locus 282 so that FET driver 294 also receives the PULSE signal from pulse signal locus 282 as an input signal. FET drivers 292, 294 are established in an operative condition or in an inoperative condition in response to a SHUTDOWN signal applied at control terminals 300, 302. FET drivers 292, 294 produce switching output signals at output lines 304, 306 in response to signals received at input terminals 296, 298. Output line 304 is coupled with a switch 310. Switch 310 operates in response to high switching output signals on output line 304 by closing to connect an input locus 311 with ground 322 in a circuit including an inductor 324 and a capacitor 326. An input signal V_{IN} is provided at input locus 311. Inductor 324 and capacitor 326 represent impedance of a load coupled with an output locus 320. Thus, closing switch 3100 results in output locus 320 being established at a potential substantially equal with input signal V_{IN}. Switch 312 is configured with an inverter 313. Thus, switch 312 operates in response to low switching output signals on output line 306 by closing to connect ground 322 with output locus 320 in a circuit including inductor 324 and capacitor 326. Closing switch 312 results in output locus 320 being established at a potential substantially equal with ground 322. Switching FET drivers 292, 294 and switches 310, 312 may be configured in any of several manners so that switches 310, 312 cannot be in the same state at the same time. That is, either switch 310 is open and switch 312 is closed, or switch 310 is closed and switch 312 is open. Such various arrangements may include providing an inverter at either of FET drivers 292, 294; providing an inverter at either of switches 310, 312 (as illustrated in FIG. 5) or another arrangement. Switches 310, 312 are preferably embodied in FETs.

Output locus 320 is coupled with sense terminal 266 of error amplifier 262; the connection may be effected via a compensation network 336. Another compensation network 338 establishes a feedback circuit for error amplifier 262 between error locus 268 and sense terminal 266. Compensation networks 336, 338 set circuit parameters for ensuring proper operation of error amplifier 262, as can be understood by one skilled in the art of switched regulator design. Details of compensation networks 336, 338 are omitted here in order to simplify explaining the present invention.

Output locus 320 is coupled with a voltage supply locus 400 for providing supply voltage V ₁ to supported device 174. In similar fashion, power supply device 186 provides supply voltage V₂ to a voltage supply locus 402, power supply device 190 provides supply voltage V₃ to a voltage supply locus 404 and power supply device 196 provides supply voltage Vₙ to a voltage supply locus 406.

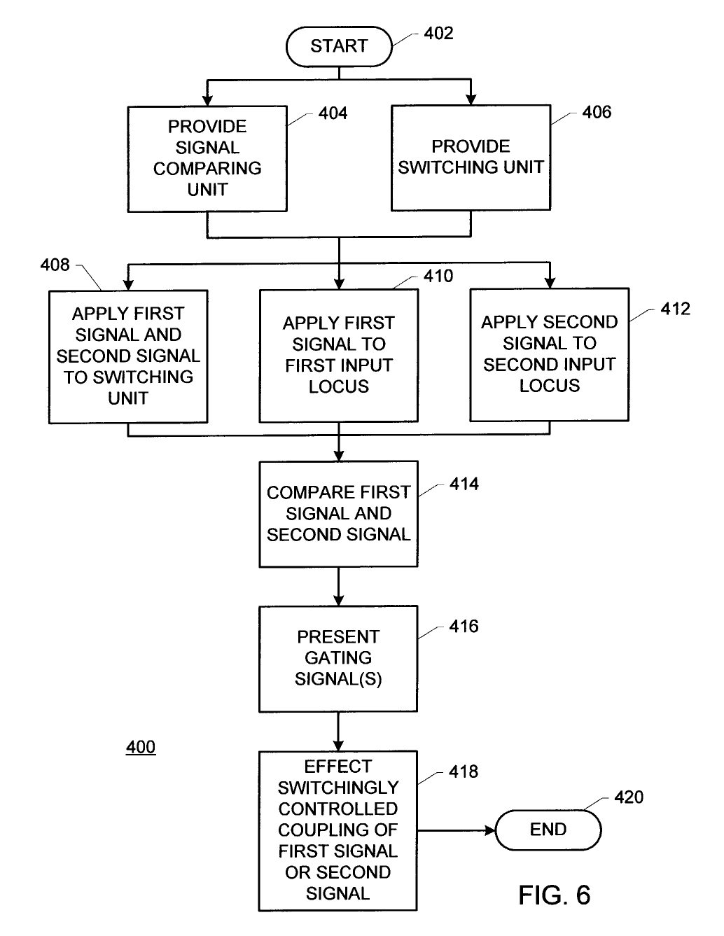

FIG. 6 is a flow diagram illustrating the method of the present invention. In FIG. 6, a method 400 for providing a signal having a controlled transition characteristic at an output terminal begins at a START locus 402. Method 400 continues with, in no particular order, providing a signal comparing unit having a plurality of input loci and at least one output locus, as indicated by a block 404, and providing a switching unit coupled with the at least one output locus, as indicated by a block 406. Method 400 continues with, in no particular order, applying a first signal and a second signal to the switching unit, as indicated b a block 408, applying the first signal at a first input locus of the plurality of input loci, as indicated by a block 410 and applying the second signal at a second input locus of the plurality of input loci, as indicated by a block 412.

Method 400 continues with comparing the first signal and the second signal in the signal comparing unit to determine relative values of the first signal and the second signal, as indicated by a block 414. Method 40 continues with presenting at least one gating signal at the at least one output locus, as indicated b a block 416. The at least one signal has a value depending on the relative values ascertained pursuant to the method step represented by block 414.

Method 400 continues with effecting switchingly controlled coupling by the switching unit of the first signal or of the second signal with the output terminal in response to the at least one gating signal, as indicated by a block 418. Method 400 then terminates, as indicated by an END locus 420.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following claims:

I claim:

1. An apparatus for providing a signal at an output terminal; said output signal having a controlled transition characteristic; the apparatus comprising:
(a) a signal comparing unit; said signal comparing unit having a plurality of input loci and at least one output locus; said signal comparing unit receiving a first signal at a first input locus of said plurality of input loci and receiving a second signal at a second input locus of said plurality of input loci; said signal comparing unit presenting at least one gating signal at said at least one output locus; said at least one gating signal having a value depending on relative values of said first signal and said second signal; and
(b) a switching unit; said switching unit being coupled with said at least one output locus and receiving said first signal and said second signal; said switching unit switchingly control coupling of said first signal or of said second signal with said output terminal in response to said at least one gating signal.

2. An apparatus for providing a signal at an output terminal as recited in claim 1 wherein said signal comparing unit includes a first comparing device and a second comparing device; said first comparing device generating a first gating signal of said at least one gating signal at a first output locus of said at least one output locus and said second comparing device generating no gating signal when said second signal is less than said first signal; said second comparing device generating a second gating signal of said at least one gating signal at a second output locus of said at least one output locus and said first comparing device generating no gating signal when said first signal is less than said second signal.

3. An apparatus for providing a signal at an output terminal as recited in claim 2 wherein said switching unit includes a first switching device coupled with said first output locus and a second switching device coupled with said second output locus; said first switching device responding to said first gating signal to switchingly interrupt said coupling of said first signal with said output terminal; said second device responding to said second gating signal to switchingly interrupt said coupling of said second signal with said output terminal.

4. An apparatus for providing a signal at an output terminal as recited in claim 1 wherein said signal comparing unit includes a comparing device and an inverter device; said comparing device generating a first gating signal of said at least one gating signal at a first output locus of said at least one output locus when said second signal is less than said first signal; said inverter device being coupled with said first output locus and receiving said first gating signal; said inverter device generating a second gating signal at a second output locus of said at least one output locus; said second gating signal being substantially the inverse of said first gating signal.

5. An apparatus for providing a signal at an output terminal as recited in claim 4 wherein said switching unit includes a first switching device coupled with said first output locus and a second switching device coupled with said second output locus; said first switching device responding to said first gating signal to switchingly interrupt said coupling of said first signal with said output terminal; said second switching device responding to said second gating signal to switchingly interrupt said coupling of said second signal with said output terminal.

6. An apparatus for providing a signal at an output terminal as recited in claim 1 wherein said signal comparing unit and said switching unit cooperate to effect said switchingly controlled coupling; and wherein said switching unit includes a first switching device coupled with a first output locus of said at least one output locus and a second switching device coupled with a second output locus of said at least one output locus; said first switching device responding to a first gating signal of said at least one gating signal to switchingly interrupt said coupling of said first signal with said output terminal; said second switching device responding to a second gating signal of said at least one gating signal to switchingly interrupt said coupling of said second signal with said output terminal.

7. An apparatus for providing a signal at an output terminal as recited in claim 1 wherein said signal comparing unit includes a first comparing device and a second comparing device; said first comparing device generating a first gating signal of said at least one gating signal at a first output locus of said at least one output locus and said second comparing device generating no gating signal when said second signal is substantially equal to or less than said first signal; said second comparing device generating a second gating signal of said at least one gating signal at a second output locus of said at least one output locus and said first comparing device generating no gating signal when said first signal is substantially equal to or less than said second signal.

8. An apparatus for providing a signal at an output terminal as recited in claim 7 wherein said switching unit includes a first switching device coupled with said first output locus and a second switching device coupled with said second output locus; said first switching device responding to said first gating signal to switchingly interrupt said coupling of said first signal with said output terminal; said second switching device responding to said second gating signal to switchingly interrupt said coupling of said second signal with said output terminal.

9. An apparatus for providing a signal at an output terminal as recited in claim 1 wherein said signal comparing unit includes a comparing device and an inverter device; said comparing device generating a first gating signal of said at least one gating signal at a first output locus of said at least one output locus when said second signal is substantially equal to or less than said first signal; said inverter device being coupled with said first output locus and receiving said first gating signal; said inverter device generating a second gating signal at a second output locus of said at least one output locus; said second gating signal being substantially the inverse of said first gating signal.

10. An apparatus for providing a signal at an output terminal as recited in claim 9 wherein said switching unit includes a first switching device coupled with said first output locus and a second switching device coupled with said second output locus; said first switching device responding to said first gating signal to switchingly interrupt said coupling of said first signal with said output terminal; said second switching device responding to said second gating signal to switchingly interrupt said coupling of said second signal with said output terminal.

11. A method for providing a signal at an output terminal; said output signal having a controlled transition characteristic; the method comprising the steps of:
(a) in no particular order:
(1) providing a signal comparing unit; said signal comparing unit having a plurality of input loci and at least one output locus; and
(2) providing a switching unit; said switching unit being coupled with said at least one output locus;
(b) in no particular order:
(1) applying a first signal and a second signal to said switching unit;
(2) applying said first signal at a first input locus of said plurality of input loci; and
(3) applying said second signal at a second input locus of said plurality of input loci;
(c) comparing said first signal and said second signal in said signal comparing unit to determine relative values of said first signal and said second signal;
(d) presenting at least one gating signal at said at least one output locus; said at least one gating signal having a value depending on said relative values; and
(e) effecting switchingly controlled coupling by said switching unit of said first signal or of said second signal with said output terminal in response to said at least one gating signal.

12. A method for providing a signal at an output terminal as recited in claim 11 wherein said signal comparing unit includes a first comparing device and a second comparing device; said first comparing device generating a first gating signal of said at least one gating signal at a first output locus of said at least one output locus and said second comparing device generating no gating signal when said second signal is substantially equal to or less than said first signal; said second comparing device generating a second gating signal of said at least one gating signal at a second output locus of said at least one output locus and said first comparing device generating no gating signal when said first signal is substantially equal to or less than said second signal.

13. A method for providing a signal at an output terminal as recited in claim 12 wherein said switching unit includes a first switching device coupled with said first output locus and a second switching device coupled with said second output locus; said first switching device responding to said first gating signal to switchingly interrupt said coupling of said first signal with said output terminal; said second switching device responding to said second gating signal to switchingly interrupt said coupling of said second signal with said output terminal.

14. A method for providing a signal at an output terminal as recited in claim 11 wherein said signal comparing unit includes a comparing device and an inverter device; said comparing device generating a first gating signal of said at least one gating signal at a first output locus of said at least one output locus when said second signal is substantially equal to or less than said first signal; said inverter device being coupled with said first output locus and receiving said first gating signal; said inverter device generating a second gating signal at a second output locus of said at least one output locus; said second gating signal being substantially the inverse of said first gating signal.

15. A method for providing a signal at an output terminal as recited in claim 14 wherein said switching unit includes a first switching device coupled with said first output locus and a second switching device coupled with said second output locus; said first switching device responding to said first gating signal to switchingly interrupt said coupling of said first signal with said output terminal; said second switching device responding to said second gating signal to switchingly interrupt said coupling of said second signal with said output terminal.

16. A method for providing a signal at an output terminal as recited in claim 11 wherein said signal comparing unit and said switching unit cooperate to effect said switchingly controlled coupling; and wherein said switching unit includes a first switching device coupled with a first output locus of said at least one output locus and a second switching device coupled with a second output locus of said at least one output locus; said first switching device responding to a first gating signal of said at least one gating signal to switchingly interrupt said coupling of said first signal with said output terminal; said second switching device responding to a second gating signal of said at least one gating signal to switchingly interrupt said coupling of said second signal with said output terminal.
